(19) United States
(12) Patent Application Publication
(10) Pub. No.: US 2004/0201100 A1
(43) Pub. Date: Oct. 14, 2004

(54) Integrated optical receiver

(76) Inventors: Desmond Lim, Singapore (SG); Kevin Lee, Cambridge, MA (US); Kazumi Wada, Lexington, MA (US)

Correspondence Address: EDWARDS & ANGELL, LLP, P.O. BOX 55874, BOSTON, MA, 02205, US

(21) Appl. No.: 10/413,456

(22) Filed: Apr. 14, 2003

(51) Int. Cl. H01L 23/48

(52) U.S. Cl. 257/758

(57) ABSTRACT

An integrated optical receiver device includes a substrate. At least one polycrystalline indirect band-gap detector capable of detecting the photons of impinging light and outputting a signal in response thereto is disposed on the substrate. At least one electronic device, electrically coupled to the at least one polycrystalline indirect band-gap detector, capable of processing the signal output by the at least one polycrystalline indirect band-gap detector is monolithically integrated with the detector on the substrate.

### BACKGROUND OF THE INVENTION

1. Field of the Invention

The present invention is directed to a receiver for use in the field of communications, specifically a receiver to be used in high bandwidth optical communications for short (centimeters) to medium distances (100s of kilometers), and in particular a receiver having a detector.

2. Prior Art

Optical communication using light at 850 nm or 1310 nm is widely used for short to medium distance communications for the transmission of data, voice, and video through network equipment. As is known in the art, the use of Wavelength Division Multiplexing (WDM) through single mode fiber will enhance the bandwidth of single mode fiber. However, efforts to incorporate WDM in these optical communications lines will be stymied by the cost of components and modules. Reducing the cost of these components and modules requires more component level integration. One area of active research is integrating optical detectors with signal processing electronics to reduce the cost of WDM components and communication components in general. However, the difficulties with integrating detectors with electronics to produce low cost electronics stem from the complexity of the integration process particularly when trying to produce monolithically integrated detectors and electronic platform.

There are two major types of detectors for near UV to far infrared frequencies. The first type of detector collects electron-hole pairs generated by photons, which are more energetic than the band-gap of the material. Metal Semiconductor Metal (MSM) and p-i-n devices are examples of such detectors. These detectors rely on charge collection for detection and are the type generally used in telecommunications applications. The second type of detector, known as a bolometer, utilizes a change in the resistance of the detector, which results from impinging photons being absorbed and heating up the detector material. The present invention concerns itself with the first type of detector, and from this point on the term detector will be restricted to this narrower definition.

Previous attempts to monolithically integrate detectors with electronics have centered on fabricating the detectors with single crystalline materials. These single crystalline detectors exhibit larger carrier lifetime and are suited to collecting photon generated charge carriers. For a monolithically integrated single crystal detector integrated with electronics, epitaxial growth is often necessary. Epitaxy requires specialized equipment, specially treated substrates and processing. The growth conditions of epitaxy require temperatures that are normally higher than processing of the electronic platform; typically >700° C., depending on the specific process in question. Therefore, materials used for the electronic device degrade at temperatures greater than 700° C.

Epitaxy of single crystalline materials normally requires that the underlying substrate be single crystalline. For integration of detectors with silicon electronics, this means that the detector has to be grown directly on the silicon wafer substrate or on top of a buffer layer, which is grown epitaxially to raise the position of the detector with respect to the substrate. Epitaxial growth of single crystalline detector materials almost always necessitates growth from the single crystal substrate and a high process temperature, in excess of 700° C. The combination of high temperature growth and single crystal substrate used in combination with electronic device fabrication restricts the process window for such detectors.

Masini et al have grown a polycrystalline Ge detector [G. Masini, L. Colace, G. Assanto, Optical Materials 17, 243-246, 2001.] on SOI material. However, this was a germanium detector device, which was not integrated with electronics and no description was given as to how to integrate this detector with electronics and/or waveguides. Furthermore this detector suffered from poor responsivity and large dark current.

Accordingly, a method and apparatus for integrating an optical detector with signal processing electronics, which overcomes the shortcomings of the prior art is desired.

### SUMMARY OF THE INVENTION

The integrated receiver includes a substrate. At least one polycrystalline indirect band gap detector for detecting photons of impinging light and outputting a signal in response thereto is disposed on the substrate. At least one electronic device capable of processing the signal output by the detector device is monolithically integrated with the detector on the substrate.

### BRIEF DESCRIPTION OF THE DRAWINGS

In the drawing figures, which are not to scale, and which are merely illustrative, and wherein like reference numerals depict like elements throughout the several views:

FIG. 1 is a schematic view of an optical receiver constructed in accordance with the invention;

FIG. 2 is a schematic cross sectional view of a p-i-n detector constructed in accordance with the invention;

FIG. 3a is a schematic cross-sectional view of a metal semiconductor metal detector constructed in accordance with the invention;

FIG. 3b is a schematic cross-sectional view of a metal semiconductor metal detector constructed in accordance with another embodiment of the invention; and

FIG. 4 is a schematic view of a detector integrated with a waveguide in accordance with the invention.

### DETAILED DESCRIPTION OF THE INVENTION

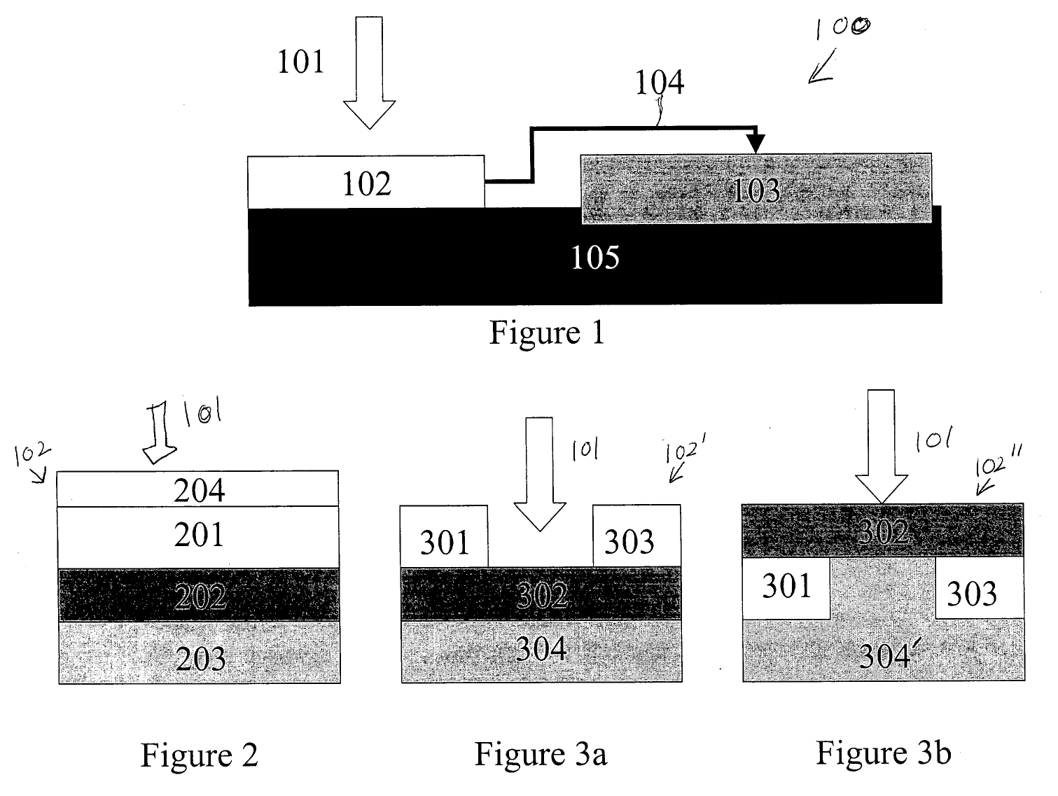

Reference is first had to FIG. 1, wherein an integrated receiver device constructed in accordance with the invention, generally indicated as 100, includes at least one polycrystalline indirect band-gap detector device 102, capable of detecting photons, connected to at least one electronic device 103, such as an amplifier, capable of amplifying the received signal. A substrate 105 is provided. A polycrystalline detector 102 is disposed on substrate 105. At least one electronic device 103 such as an amplifier, switch activator, or other electronic component capable of processing a signal, is disposed on substrate 105 and is electrically connected to detector 103.

In operation, photons of incident light 101 impinge on the polycrystalline detector 102 to produce a current in response thereto. The resulting current can be electrically connected, as shown by way of example as input 104 to electronic device 103 to make a monolithically integrated receiver. Both detector 102 and electronic device 103 are integrated on the same substrate 105. The benefit of such a monolithically integrated polycrystalline detector and electronic integrated receiver device is the relative ease with which polycrystalline materials can be integrated with other electronics.

Polycrystalline materials can be grown under a much wider range of processing conditions than single crystalline materials and do not require specially treated substrates. As a result, the formation of polycrystalline detector 102 facilitates integration with associated electronic components, at temperatures that can be compatible with electronics backend processing, and on substrates which are not crystalline. Polycrystalline materials can be easily deposited on other polycrystalline and amorphous materials, including metals, dielectrics such as silica, or polycrystalline silicon.

FIG. 2 shows a schematic cross section of one embodiment of a detector 102 constructed in accordance with the invention. Detector 102, in this embodiment is a p-i-n detector. In this embodiment, detector 102 includes a first doped region 203 and second doped region 201. An absorbing region 202 is disposed between doped regions 201, 203. In a preferred embodiment, but not necessary for operation of the invention, an antireflection coating 204 is disposed upon the doped region (in this case doped layer 201) upon which light 101 first impinges.

The absorbing region 202 is in contact with doped layers 203 and 201, which are doped degenerately p and n respectively or vice versa. Light impinges through coating 204, which is an optional anti-reflection coating. As is known, electron hole pairs are generated in the absorbing layer 202 as a result of receiving the light. The electron-hole pairs that are generated are then separated and collected at doped layers 203 and 201 producing a current, which is input as a signal to electronic device 103. Detector device may then operate on the signal depending upon the nature of the device. For example, an amplifier would amplify the signal.

Reference is now made to FIGS. 3a and 3b which show a schematic cross section of an MSM detector 102′ for use in accordance with a second embodiment of the invention.

Absorbing region 302 is in contact with metals 303 and 301. Detector 102′ includes a substrate 304. Absorbing layer 302 is disposed on substrate 304. First metal layer 301 is disposed on absorbing layer 302 and a second metal layer 303 is also disposed on absorbing layer 303, separated by distance from first metal layer 301 to expose absorbing layer 302 to light 101.

The photons from light 101 impinge on absorbing layer 302 and generate electron-hole pairs that are then separated and collected at respective metal layers 303 and 301 to produce current to be input to electronic device 103.

In both embodiments of receiver 100, an absorbing layer formed from an indirect band-gap material is used as the detector regions 202, 302 and detector regions 202, 302 are electrically connected to at least one electronic device 103. Many current MSM devices have metal contacts disposed between incident light 101 and the detector material of absorbing layer 302 as shown in FIG. 3a. However, these MSM devices have a limitation because the metal absorbs the incoming light and reduces the responsivity of the detector. With polycrystalline detectors, it is possible to have the metal buried in the detector, or to deposit the detector layer on top of the metal. This allows the light to impinge and be detected without obstruction from the metal contacts of the detector.

Reference is now made to FIG. 3b, in which a third embodiment of a detector generally indicated as 102″, is provided. Like numerals are utilized to indicate like structures, the primary difference being the position of metal contacts 301, 303 with respect to detector region 302 and substrate 304′.

In this embodiment, metal layers 301, 303 are disposed directly upon substrate 304′ and may be separated from each other by substrate 304′. Absorbing layer 302 is disposed on metal layers 301, 303 as well as substrate 304′, if such substrate 304′ in fact extends between metal layers 301, 303. In this way, impinging light 101 fully impinges on absorbing layer 302 without being blocked by metal layers 301, 303.

A key point to note for polycrystalline detectors is that they have to be transit time limited, that is the time of flight of the electron or hole in the semiconductor must be less than the recombination time of the electron-hole pair. Lifetime is an important issue in detectors because a low lifetime material can cause electron-hole pair recombination, which in turn reduces the amount of charge that can be collected, limiting the current output to the electronic device and hence the responsivity of the device. In general, polycrystalline materials have shorter lifetimes than their single crystalline counterparts. For direct band-gap materials, the dangling bonds grain boundaries of a polycrystalline material will cause a large enough amount of electron hole recombination so that a polycrystalline detector has been considered to be extremely inefficient. However, for indirect band-gap polycrystalline materials the lifetimes of the materials are longer. If the quality of the indirect band-gap polycrystalline material is sufficient to ensure carrier sweep out times of order of the lifetime of the material (or less), the detector will be useful. In other words, the carrier lifetime of the material, the recombination time, which contributes to the lifetime, must be longer than the transit times. Examples of indirect band-gap materials include doped or undoped silicon, germanium, silicon germanium alloys and in general group IV alloys. These group IV alloy materials are particularly useful since they can be easily integrated on a silicon substrate.

The dangling bonds at the grain boundaries of the polycrystalline detection material can be suppressed by thermal annealing as well as by annealing in an ambient that would passivate the dangling bonds. For example, annealing polycrystalline silicon germanium in hydrogen rich ambient suppresses the dangling bonds at the grain boundaries, mitigating electron-hole recombination and increasing the number of carriers that are collected in a detector. Examples of hydrogen rich environment are forming gases. Alternatively, the material may be deposited in a hydrogen rich environment or from precursors with high hydrogen content, such as Silane or Germane. This last method best facilitates for low temperature processing.

The suppression of the dangling bonds is also important because it allows for reduced dark current. Dark current is the amount of current conducted by the detector in reverse bias when the detector has received no light. One of the primary causes of dark current in a reversed biased junction device is the presence of impurities or defects in the depleted region, which, in turn, allows the conduction of current through the junction. There are two ways around this problem. The first is to suppress the dangling bonds at the defects as mentioned above, and the second is to reduce the cross sectional area of the detector, thereby reducing the number of defects in the junction.

Reducing the area of the detector of course requires the detector and its associated optics to be designed so that light impinging on the detector is focused on a smaller spot. This may be done in several ways. The first is to use a lens to focus the light to a smaller spot, the second is to use a waveguide, which is coupled to the detector to deliver the light in a small area. Both these methods are predicated on having a high enough absorption coefficient in the material to reduce the size of the depleted region. Furthermore, the size of the detector cannot be made arbitrarily small because saturation effects will take over.

A person skilled in the art will also recognize that significant electron hole recombination occurs at the surfaces or interfaces of the detector. To minimize electron-hole recombination at these areas a layer of passivation may be required. Such passivation may take the form of deposited oxides or thermally grown oxides or another semiconductor material. Deposited oxides are preferable for low temperature integration while thermally grown oxides are preferable for better suppression of electron-hole recombination at the interfaces.

The interface quality between the detector material and its underlying non-detecting material is important for a different reason. Oftentimes, this interface needs to be free of impurities and damage to increase the electrical conductivity across this interface. The use of plasma cleaning and cluster tooling in the toolsets as known in the art can allow growth of films with very little intervening oxide between the layer that is grown and the material that the layer is grown on.

Another key issue for polycrystalline materials is to ensure that the material has an absorption coefficient, which is large enough to ensure significant absorption in a small propagation distance. Once again, this allows a person skilled in the art to design a detector with carrier sweep out times that are small enough to be smaller than the lifetime of the electrons and holes in the detector region. In a preferred embodiment in which detector 102 is near IR detector that would be sensitive at wavelengths shorter than 1550 nm, doped poly-Si (polycrystalline silicon) is used for (contacts) doped layers 201, 203 and poly-SiGe (polycrystalline SiGe) or poly-Ge (polycrystalline Ge) is used for (detector region) absorption layer 202. In a preferred embodiment, absorption layer 202 is made of polycrystalline SiₓGe_{y}Sn_{z}C_{1-x-y-z}alloy. Poly-Ge has an absorption coefficient of 10⁴ cm⁻¹ at wavelengths less than or equal to 1550 nm, making it a suitable material for detection at these wavelengths. Other indirect band-gap materials are GₐP, AIP, AlAs and AlSb. FIG. 2 shows a schematic of such a detector implemented as a top illuminated, large area photo detector. In this embodiment, doped layer 203 is a poly-Si seed layer, which is used for growth of the poly-SiGe or poly-Ge. This poly-Si layer can be grown on top of a dielectric layer or a metal layer.

Growing the detector on a dielectric layer has the advantage of ease of integration, since the dielectric thickness can be tailored to position the detector. In addition, the detector can be electrically and optically isolated from any underlying electronics, allowing for greater flexibility in integration schemes. Further, a poly-Si cap layer is deposited on top of the poly-SiGe or poly-Ge to act as the electrode. The cap layer may also serve a different purpose: the poly-Si cap layer may be oxidized to provide a silicon oxide layer to minimize electron-hole recombination at the surfaces.

Silicon substrates are particularly attractive since they allow for the integration of the detector device with high-speed industry standard electronics, such as Si CMOS, BiCMOS, and BJT technology, or SiGe technology. These electronics technologies allow the detector to be integrated with high-speed electronics in a low cost manner. Examples of electronic device 103 circuitry that may be important to implement in an integrated receiver include but are not limited to TIAs, CDRs, LNAs. Silicon is by no means the only substrate. A person skilled in the art can use any substrate on which electronics can be fabricated.

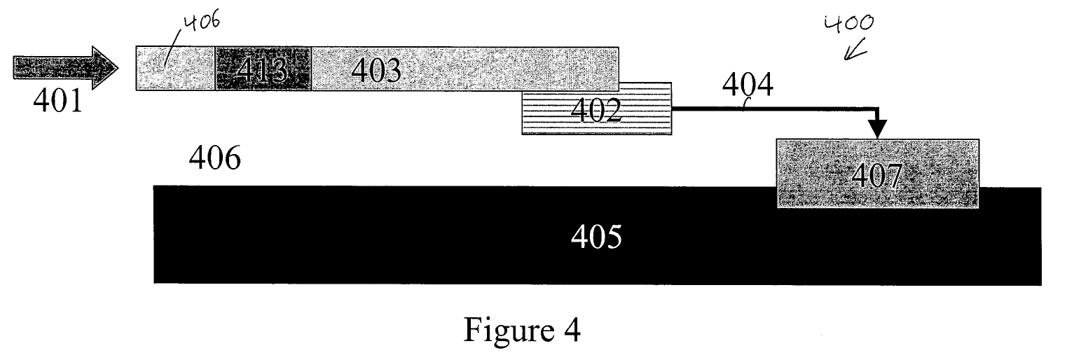

Reference is now made to FIG. 4, in which another embodiment of this invention, a waveguide is integrated with a polycrystalline detector generally indicated as 400 in which a detector and associated electronics are provided. The polycrystalline detector significantly reduces the process integration complexities of putting waveguides, detectors and associated electronics together on the same substrate. A substrate 405 is provided. At least one electronic device 407 is disposed on substrate 405. A detector 402 may be disposed on substrate 405, however, detector 402 is electronically coupled to provide an input 404 to electronic device 407. A waveguide 403 is optically coupled to detector 402 to input light 401 to detector 402.

Light 401 in waveguide 403 is detected by detector 402, shown schematically as being below the waveguide 403. Nevertheless, the position of the detector will be optimized to increase the amount of light coupled into the detector absorption region. As before the detector 402 is connected electronically to electronic circuit 403, providing input 404 thereto. Detector 402, waveguide 403 and electronic device 407 are all fabricated on the same substrate.

Another significant advantage of using a polycrystalline detector is that it allows waveguides to be readily integrated with detectors even if they are at a large distance from the substrate. As shown in FIG. 4, the waveguide 403 may be a substantial distance away from substrate 405. As a result of the detector being made of polycrystalline material, the detector need not be close to or in contact with the surface of substrate 405.

In contrast thereto, single crystalline detectors often need to be close to the substrate surface. Alternatively, a buffer layer may be used to raise the position of the single crystalline detector with respect to the substrate surface; however, this is a time consuming and difficult formation process. Accordingly, polycrystalline detectors provide significantly more flexibility in detector to waveguide integration concepts lending themselves to more efficient designs. These designs are particularly important for high index difference waveguides (where the indices of the core and the cladding differ by more than about 5 percent). In this embodiment, the detector can be grown on top of an amorphous or polycrystalline dielectric material.

One embodiment of a waveguide to polycrystalline detector integration would be to change the cross-sectional area of the waveguide, such as tapered down, in the region near the detector. Alternatively, the waveguide may be butt coupled into a detector; however an anti-reflection coating or an angled face may be necessary to suppress reflection off the waveguide detector interface. In general it would be useful to have one or more planarization modules to ease integration of the waveguide, which the detector requires. Such planarization can involve reflow of one or more materials like BPSG or may involve chemo-mechanical polishing of one or more materials.

A preferred embodiment of the integrated receiver device would have a silicon nitride/oxy nitride waveguide, coupled to a Ge or SiGe detector as described above that is in turn connected to electronic device 407, such as a trans-impedance amplifier and other electronics. In one embodiment, by way of another example, waveguide 403 is coupled to an external fiber 406. A person skilled in the art may alternatively use a silicon waveguide or a doped silica waveguide (the dopant being one or more of boron, phosphorous, fluorine, nitrogen or germanium). If a high index difference waveguide is used the waveguide is preferably connected to the external fiber through a mode convertor. In addition, the waveguide may contain at least one optical waveguide function 413. The optical function can be any structure or device that is used to generate, modify, and/or measure the amplitude, frequency, wavelength, dispersion, timing, propagation direction, and/or polarization properties of one or more light pulses.

While there have been shown and described and pointed out fundamental novel features of the invention as applied to preferred embodiments thereof, it will be understood that various omissions and substitutions and changes in the form and details of the disclosed invention may be made by those skilled in the art without departing from the spirit and scope of the invention. It is the intention, therefore, to be limited only as indicated by the scope of the claims appended hereto.

1. An integrated optical receiver device consisting of
a substrate;
at least one polycrystalline indirect band-gap detector, said at least one polycrystalline indirect band gap detector detecting the photons of impinging light and outputting a signal in response thereto; and
at least one electronic device electrically coupled to said at least one polycrystalline indirect band-gap detector capable of processing said signal output by said at least one polycrystalline indirect band-gap detector, said at least one polycrystalline indirect band-gap detector and electronic device being monolithically integrated on said substrate.

2. The integrated receiver device of claim 1, wherein said at least one polycrystalline indirect band-gap detector is grown at a temperature compatible to backend processing of said at least electronic device.

3. The integrated receiver device of claim 1, wherein the substrate is formed of silicon.

4. The integrated receiver device of claim 1, wherein the at least one polycrystalline indirect band-gap includes a detector absorption region, said detector absorption region consisting of a polycrystalline Group IV alloy

5. The integrated receiver device of claim 3, wherein the detector absorption region consists of a polycrystalline SiₓGe_{y}Sn_{z}C_{1-x-y-z}alloy.

6. The integrated receiver device of claim 1, wherein the at least one polysrystalline indirect band-gap detector is an MSM device.

7. The integrated receiver device of claim 1, wherein the detector is a p-i-n device.

8. The integrated receiver of claim 1, wherein said at least one electronic device is an amplifier.

9. The integrated receiver device of claim 1, wherein said at least one polycrystalline indirect band-gap detector device is grown on a non-crystalline material region.

10. The integrated receiver device of claim 9, wherein the substrate is silicon.

11. The integrated receiver device of claim 9, wherein said polycrystalline indirect band-gap detector is grown on a poly-Si seed layer.

12. The integrated receiver device of claim 9, wherein the at least one polycrystalline indirect band-gap detector includes an absorption region, said absorption region consisting of at least one layer of polycrystalline Group IV alloy.

13. The integrated receiver device of claim 12, further comprising a poly-Si cap layer disposed on top of the layer of polycrystalline Group IV alloy.

14. The integrated receiver device of claim 13, wherein said poly-Si cap layer is oxidized to provide a silicon oxide layer to minimize electron-hole recombination.

15. The integrated receiver device of claim 10, wherein at least one polycrystalline indirect band-gap detector includes an absorption region, said absorption region consisting of at least one layer of a polycrystalline SiₓGe_{y}Sn_{z}C_{1-x-y-z}alloy.

16. The integrated receiver device of claim 9, wherein said non-crystalline material region is at least partly made of metal.

17. The integrated receiver device of claim 12, wherein the at least one polycrystalline indirect band-gap detector is an MSM device.

18. The integrated receiver device of claim 9, wherein the at least one polycrystalline indirect band-gap detector is a p-i-n device.

19. The integrated receiver device of claim 1, further comprising a waveguide, said waveguide being optically coupled to said at least one polycrystalline indirect band-gap detector; and wherein said at least one polycrystalline indirect band-gap detector detects light output by said waveguide.

20. The integrated receiver device of claim 19, wherein said waveguide is integrated with said substrate.

21. The integrated receiver device of claim 19, wherein said waveguide is formed of a compound of at least silicon and nitrogen.

22. The integrated receiver device of claim 19, wherein said waveguide is formed of one of doped and undoped silica.

23. The integrated receiver device of claim 19, wherein said waveguide is formed of silicon.

24. The integrated receiver device of claim 19, wherein said waveguide is optically connected to an external fiber.

25. The integrated receiver device of claim 19, wherein said waveguide is connected to an external fiber through a mode converter.

26. The integrated receiver device of claim 19, further comprising at least one optical waveguide function within said waveguide.

27. The integrated receiver device of claim 19, wherein said waveguide has a cross sectional shape, and said optical waveguide is coupled into said at least one polycrystalline indirect band-gap detector by changing the cross-sectional shape of the waveguide in the region near the at least one polycrystalline indirect band-gap detector.

28. The receiver device of claim 19, wherein the said waveguide and said at least one polycrystalline indirect band-gap detector are integrated by a planarization method.

29. The receiver device of claim 28, wherein said planarization method is reflow.

30. The receiver device of claim 28, wherein said planarization method is chemo-mechanical polishing.

31. The integrated receiver device of claim 31, wherein said electronic device is formed of silicon.

32. The integrated receiver device of claim 31, wherein said electronic device is formed of silicon germanium.

33. The integrated receiver device of claim 31, wherein the electronic device is a trans-impedance amplifier.

34. The integrated receiver device of claim 33, wherein said trans-impedance amplifier is connected to a clock data recovery circuit.
